(19) United States
(12) Patent Application Publication
(10) Pub. No.: US 2022/0030669 A1
(43) Pub. Date: Jan. 27, 2022

(54) CERAMIC HEATER WITH SHAFT

(71) Applicant: NGK INSULATORS, LTD., Nagoya-City (JP)

(72) Inventors: Kenichiro AIKAWA, Handa-City (JP); Hiroshi Takebayashi, Handa-City (JP); Tatsuya Kuno, Nagoya-City (JP)

(73) Assignee: NGK INSULATORS, LTD., Nagoya-City (JP)

(21) Appl. No.: 17/493,004

(22) Filed: Oct. 4, 2021

Related U.S. Application Data
(63) Continuation of application No. PCT/JP2020/022833, filed on Jun. 10, 2020.

(30) Foreign Application Priority Data
Jul. 1, 2019 (JP) 2019-122787

(51) Int. Cl. H05B 3/14; H01L 21/67; H05B 3/03

(52) U.S. Cl. CPC H05B 3/143; H05B 3/03; H01L 21/67103

(57) ABSTRACT

A ceramic heater with a shaft includes a ceramic plate in which an RF electrode and a resistance heating element are embedded; a hollow ceramic shaft provided on a surface on an opposite side of a wafer placement surface of the ceramic plate; an RF power supply rod which is housed in an inner space of the ceramic shaft, and a heating element power supply rod which is housed in the inner space of the ceramic shaft, wherein an outer circumferential surface of a portion of at least one of the RF power supply rod and the heating element power supply rod is covered with an insulating thin film which is an aerosol deposition film or a thermal spray film, the portion being located in the inner space of the ceramic shaft.

### BACKGROUND OF THE INVENTION

### 1. Field of the Invention

The present invention relates to a ceramic heater with shaft.

### 2. Description of the Related Art

In transfer, exposure, a film deposition process such as CVD, washing, etching, and micromachining such as dicing, for a semiconductor wafer, an electrostatic chuck for holding the wafer has been used so far. As shown in PTL 1, such a ceramic heater with a shaft is disclosed, which includes: a ceramic plate in which a resistance heating element is embedded; a hollow ceramic shaft provided on the surface on the opposite side of a wafer placement surface of the ceramic plate; and a heating element power supply rod housed in the inner space of the ceramic shaft (see FIG. 4). The heating element power supply rod is bonded to the resistance heating element from the surface on the opposite side of the wafer placement surface of the ceramic plate. The outer circumferential surface of a portion of the heating element power supply rod is covered with an insulating member made of ceramic, the portion being located in the inner space of the ceramic shaft.

### CITATION LIST

### Patent Literature

PTL 1: JP 2007-051317 A

### SUMMARY OF THE INVENTION

In such a ceramic heater with a shaft, when an insulating sleeve or the like is used as an insulating member covering the heating element power supply rod, the insulating sleeve needs a certain degree of thickness, thus when multiple heating element power supply rods are attempted to be housed in the inner space of the ceramic shaft, it is necessary to increase the diameter of the ceramic shaft. However, when the diameter of the ceramic shaft is increased, the temperature uniformity of the wafer placement surface and a wafer is degraded or the stress at the bonding interface between the ceramic shaft and a ceramic plate is increased, thus increase in the diameter of the ceramic shaft is limited.

The present invention has been devised to solve such a problem, and it is a main object to increase the placement density of the power supply rods while securing insulation between the power supply rods.

The ceramic heater with a shaft of the present invention includes:

a ceramic plate in which an RF electrode and a resistance heating element are embedded;

a hollow ceramic shaft provided on a surface on an opposite side of a wafer placement surface of the ceramic plate;

an RF power supply rod which is housed in an inner space of the ceramic shaft, and bonded to the RF electrode from the surface on the opposite side of the wafer placement surface of the ceramic plate; and

a heating element power supply rod which is housed in the inner space of the ceramic shaft, and bonded to the resistance heating element from the surface on the opposite side of the wafer placement surface of the ceramic plate,

wherein an outer circumferential surface of a portion of at least one of the RF power supply rod and the heating element power supply rod is covered with an insulating thin film which is an aerosol deposition film or a thermal spray film, the portion being located in the inner space of the ceramic shaft.

In the ceramic heater with a shaft, the outer circumferential surface of a portion of at least one of the RF power supply rod and the heating element power supply rod is covered with an insulating thin film which is an AD film or a thermal spray film, the portion being located in the inner space of the ceramic shaft. Thus, the thickness of the insulating thin film is sufficiently small. Therefore, the placement density of the power supply rods can be increased while securing insulation between the power supply rods. Consequently, it is possible to increase the number of power supply rods which can be housed in the inner space of the ceramic shaft, and power supply rods can be housed in the inner space of the ceramic shaft having a smaller diameter.

In the ceramic heater with a shaft of the present invention, the thickness of the insulating thin film may be 10 μm or more and 200 μm or less. In this manner, the effect of the present invention is reliably obtained.

In the ceramic heater with a shaft of the present invention, multiple zones of the ceramic plate may be provided with respective resistance heating elements, and the heating element power supply rod may be provided for each of the resistance heating elements. The present invention is particularly useful for so-called multi-zone heater in which multiple zones are provided with respective resistance heating elements.

### BRIEF DESCRIPTION OF THE DRAWINGS

FIG. 1 is a vertical cross-sectional view of a ceramic heater with a shaft of the present embodiment.

FIG. 2 is a transverse cross-sectional view of the ceramic heater with a shaft.

FIG. 3 is a transverse cross-sectional view of the ceramic heater with a shaft.

FIG. 4 is a vertical cross-sectional view of a conventional ceramic heater with a shaft.

### DETAILED DESCRIPTION OF THE INVENTION

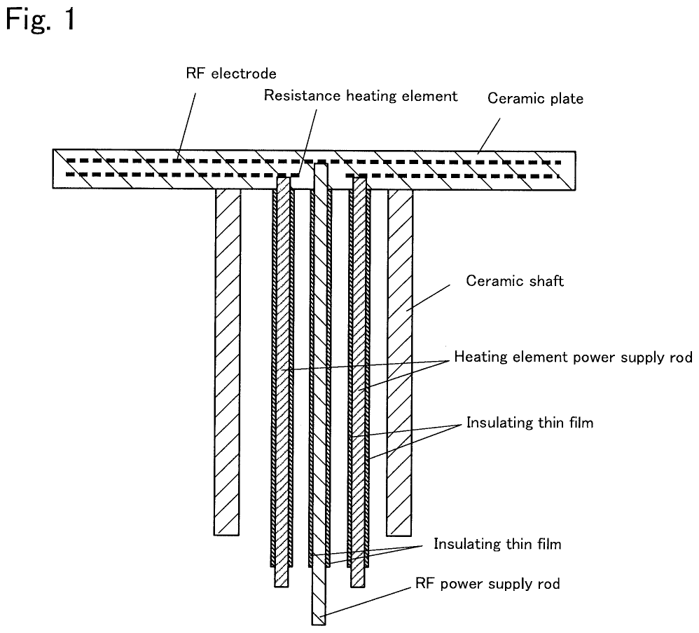

A preferred embodiment of the present invention will be described hereinafter with reference to the drawings. FIG. 1 is a vertical cross-sectional view of a ceramic heater with a shaft of the present embodiment.

As illustrated in FIG. 1, the ceramic heater with a shaft includes a ceramic plate, a ceramic shaft, an RF power supply rod, and heating element power supply rods. An RF electrode and resistance heating elements are embedded in the ceramic plate. The RF electrode is an electrode to which a high-frequency voltage is applied when plasma is generated. The resistance heating elements are respectively provided in multiple zones of the ceramic plate. The ceramic shaft is a hollow shaft which is bonded to the surface on the opposite side of the wafer placement surface of the ceramic plate by direct bonding. The RF power supply rod is housed in the inner space of the ceramic shaft, and bonded to the RF electrode from the surface on the opposite side of the wafer placement surface of the ceramic plate. The heating element power supply rods are housed in the inner space of the ceramic shaft, and bonded to the resistance heating element from the surface on the opposite side of the wafer placement surface of the ceramic plate. The heating element power supply rods are provided for respective resistance heating elements. The material for each power supply rod includes, for example, molybdenum, titanium, and nickel. The outer circumferential surface of a portion of the RF power supply rod is covered with an insulating thin film (for example, alumina thin film), the portion being located in the inner space of the ceramic shaft. The outer circumferential surface of a portion of each heating element power supply rod is covered with an insulating thin film (for example, alumina thin film), the portion being located in the inner space of the ceramic shaft. Each insulating thin film is also an AD film or a thermal spray film. Particularly, an AD method (including a plasma AD method) is suitable for forming a thin film of fine ceramic particles with high accuracy. In addition, the AD method allows a film of ceramic particles to be formed by an impact consolidation phenomenon, thus it is not necessary to sinter ceramic particles at a high temperature. It is preferable that the thickness of the insulating thin film be 10 μm or more and 200 μm or less.

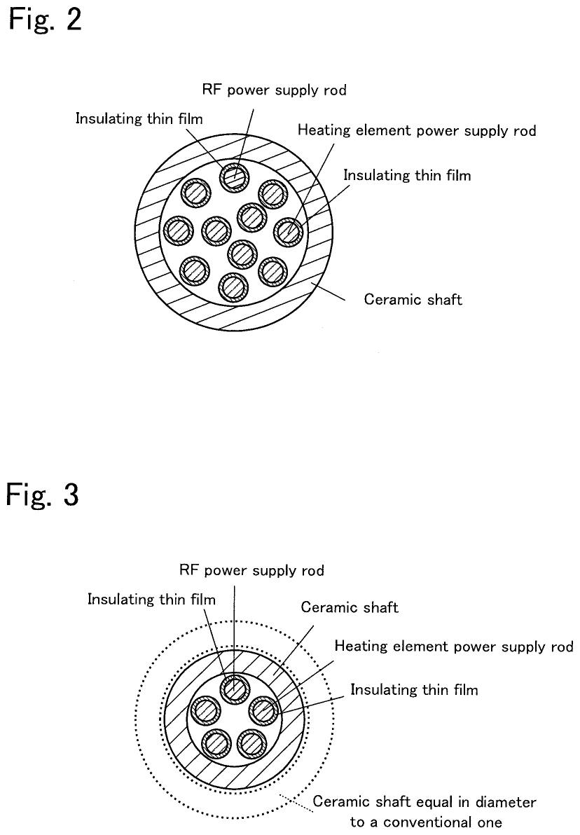

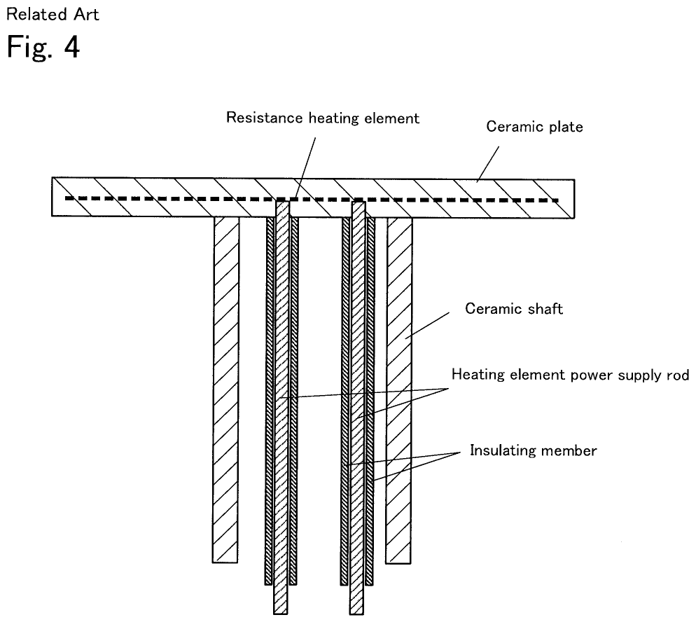

In the ceramic heater with a shaft of the present embodiment described above, the outer circumferential surface of a portion, located in the inner space of the ceramic shaft, of the RF power supply rod and the heating element power supply rods is covered with an insulating thin film which is an AD film or a thermal spray film. Thus, the thickness of the insulating thin film is sufficiently small. Therefore, the placement density of the power supply rods can be increased while securing insulation between the power supply rods. Consequently, it is possible to increase the number of power supply rods which can be housed in the inner space of a ceramic shaft equal in diameter to a conventional one (see FIG. 2), and to house power supply rods equal in number to a conventional one into the inner space of a ceramic shaft smaller in diameter than a conventional one (see FIG. 3).

In addition, it is preferable that the thickness of the insulating thin film be 10 μm or more and 200 μm or less. In this manner, the effect of the present embodiment is reliably obtained.

Note that an electrostatic electrode may be embedded in the ceramic plate.

The present invention is not limited to the above-described embodiment, and can be carried out by various modes as long as they belong to the technical scope of the invention.

The present application claims priority from JP Patent Application No. 2019-122787 filed Jul. 1, 2019, the entire contents of which are incorporated herein by reference.

What is claimed is:

1. A ceramic heater with a shaft, comprising:
a ceramic plate in which an RF electrode and a resistance heating element are embedded;
a hollow ceramic shaft provided on a surface on an opposite side of a wafer placement surface of the ceramic plate;
an RF power supply rod which is housed in an inner space of the ceramic shaft, and bonded to the RF electrode from the surface on the opposite side of the wafer placement surface of the ceramic plate; and
a heating element power supply rod which is housed in the inner space of the ceramic shaft, and bonded to the resistance heating element from the surface on the opposite side of the wafer placement surface of the ceramic plate,
wherein an outer circumferential surface of a portion of at least one of the RF power supply rod and the heating element power supply rod is covered with an insulating thin film which is an aerosol deposition film or a thermal spray film, the portion being located in the inner space of the ceramic shaft.

2. The ceramic heater with a shaft according to claim 1,
wherein a thickness of the insulating thin film is 10 μm or more and 200 μm or less.

3. The ceramic heater with a shaft according to claim 1,
wherein multiple zones of the ceramic plate are respectively provided with resistance heating elements each of which is the resistance heating element, and
the heating element power supply rod is provided for each of the resistance heating elements.
